(19) United States
(12) Patent Application Publication
(10) Pub. No.: US 2023/0101541 A1
(43) Pub. Date: Mar. 30, 2023

(54) BOTTOM ANTIREFLECTIVE COATING COMPOSITION FOR USE WITH OVERLYING PHOTORESIST AND METHOD FOR FORMING PHOTORESIST RELIEF IMAGE

(71) Applicant: Xiamen Hengkun New Material Technology Co., Ltd., Xiamen City (CN)

(72) Inventors: Hongchao Mao, Xiamen (CN); Hehe Li, Xiamen City (CN); Jing Wang, Xiamen City (CN); Nan Xiao, Xiamen City (CN)

(73) Assignee: Xiamen Hengkun New Material Technology Co., Ltd., Xiamen City (CN)

(21) Appl. No.: 17/819,490

(22) Filed: Aug. 12, 2022

(30) Foreign Application Priority Data
Aug. 30, 2021 (CN) 202111003136.4

(51) Int. Cl. G03F 7/16; G03F 7/09

(52) U.S. Cl. CPC G03F 7/161; G03F 7/091; G03F 7/092

(57) ABSTRACT

A bottom antireflective coating composition and a method for forming a photoresist relief image. The coating composition comprises a resin containing a structural unit represented by the Formula (1), a structural unit represented by the Formula (2), and a structural unit represented by the Formula (3):

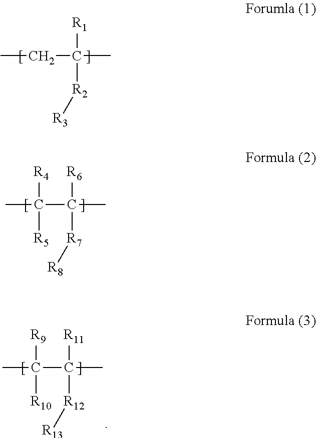

The structural unit represented by the Formula (1), the structural unit represented by the Formula (2), and the structural unit represented by the Formula (3) is present in the resin in a molar ratio of (0.1-1000):(0.1-1000):1.

### CROSS REFERENCE TO RELATED APPLICATION

This patent application claims the benefit and priority of Chinese Patent Application No. 202111003136.4, filed on Aug. 30, 2021, the disclosure of which is incorporated by reference herein in its entirety as part of the present application.

### TECHNICAL FIELD

The present disclosure is related to the field of photoresists, and in particular to a bottom antireflective coating composition and a method for forming a photoresist relief image.

### BACKGROUND ART

Photoresists are light-sensitive compositions that can be used for the transfer of images to a substrate. A coating layer of a photoresist is formed on a substrate and then exposed through a photomask to a source of activating radiation. The photomask has areas that are transparent to activating radiation and other areas that are opaque to activating radiation. Exposure to activating radiation can induce a photoinduced or chemical change to the photoresist coating. Thereby, the pattern of the photomask can be transferred to the substrate coated with the photoresist. After exposure, the photoresist is developed to produce a relief image that permits selective processing of the substrate.

Photoresists are used in microlithography processes for the fabrication of computer chips and integrated circuits where an objective is to convert a semiconductor wafer, such as silicon or gallium arsenide, into a complex matrix of electron conducting paths that perform circuit functions. Proper photoresist processing is a key to attaining this objective. While there is a strong interdependency among the various photoresist processing steps, exposure is believed to be one of the most important steps in attaining high resolution photoresist images.

The trend towards miniaturization and high integrity of semiconductor devices has promoted the application of deep ultraviolet (UV) exposure technologies, such as, lasers that emit radiation at 248 nm and 193 nm, as well as the use of new photoresists that are sensitive to lower wavelengths of radiation. The effects of standing waves formed in the interior of the photoresist by reflection of radiation from the substrate are significant in such exposure technologies, resulting in a non-uniform exposure of the photoresist and jaggies in the images and thereby non-uniform photoresist linewidth. These problems can finally lead to short or open circuits and affect the yield of the photolithographic process.

One approach used to reduce the problem of reflected radiation has been the use of a light absorption layer (i.e. a bottom antireflective coating) interposed between the substrate and the photoresist coating layer. Before a photoresist is coated onto a substrate, a bottom antireflective coating layer is formed on the substrate. A coating layer of the photoresist is formed on the bottom antireflective coating layer and then subjected to exposure and development processes. The bottom antireflective material in the exposed areas is usually etched using an oxygen plasma. Then, the photoresist pattern can be transferred to the substrate. Depending on the particular application, a proper bottom antireflective coating material composition is selected to provide desired characteristics, such as absorption and coating properties. Electronic device manufacturers are continually striving to improve the resolution of the photoresist image patterned over antireflective coating layers, which imposes higher demand on the performance of the bottom antireflective coating compositions.

One of the major problems with prior art bottom antireflective coating compositions, that urgently needs to be solved, is that the thickness of coating films of such compositions varies widely before and after cure leading to a high rate of shrinkage of the films and adversely affecting their antireflective property and etch resolution.

### SUMMARY

To overcome the above-described problem, that is, the problem that the thickness of coating films of prior art bottom antireflective coating compositions varies widely before and after cure leading to a high rate of shrinkage of the films, there are provided a new bottom antireflective coating composition and a method for forming a photoresist relief image. The coating composition according to the present disclosure enables a greatly reduced variation in thickness of a bottom antireflective coating film formed thereby before and after cure and thus improved quality of a photoresist image patterned over the coating film.

One aspect of the present disclosure provides a bottom antireflective coating composition, comprising a resin containing a structural unit represented by the Formula (1), a structural unit represented by the Formula (2), and a structural unit represented by the Formula (3):

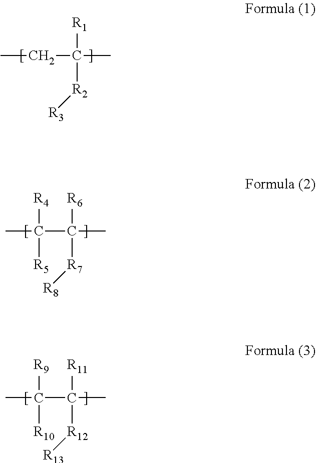

In the Formula (1), R₁ is a hydrogen atom, a chlorine atom, an optionally substituted alkyl, or an optionally substituted cycloalkyl; R₂ is —C(═O)—O—, —O—, —(CH₂)ₙ₁—O—, —O—(CH₂)ₙ₂—, —(CH₂)ₙ₃—, —Ar₁—O—, —O—Ar₂—, or —Ar₃—, with n1 and n2 each being a positive integer and n3 being a non-negative integer, and each of Ar₁, Ar₂, and Ar₃ being independently an optionally substituted carbocyclic aryl or an optionally substituted heteroaryl; R₃ is a chlorine atom, an optionally substituted alkyl, or an optionally substituted cycloalkyl; and at least one of R₁ and R₃ is a chlorine atom.

In the Formula (2), R₄, R₅, and R₆ are each independently a hydrogen atom, an optionally substituted alkyl, or an optionally substituted cycloalkyl; R₇ is defined as for R₂; and R₈ is an optionally substituted alkyl or an optionally substituted cycloalkyl and contains at least one tertiary amino group.

In the Formula (3), R₉, R₁₀, and R₁₁ are each independently a hydrogen atom, an optionally substituted alkyl, or an optionally substituted cycloalkyl; R₁₂ is defined as for R₂; and R₁₃ is a hydrogen atom, an optionally substituted alkyl, an optionally substituted cycloalkyl, or an optionally substituted aryl.

The structural unit represented by the Formula (1), the structural unit represented by the Formula (2), and the structural unit represented by the Formula (3) is present in the resin in a molar ratio of (0.1-1000):(0.1-1000):1.

In an embodiment, in the Formula (1), R₁ is a hydrogen atom, a chlorine atom, or a C₁-C₅ straight alkyl; R₂ is —C(═O)—O—, —(CH₂)ₙ₁—O—, —O—(CH₂)ₙ₂—, —(CH₂)ₙ₃—, —Ar₁—O—, —O—Ar₂—, or —Ar₃—, with n1 and n2 each being a positive integer ranging from 1 to 6 and n3 being a non-negative integer ranging from 0 to 6, Ar₁ being an optionally substituted C₆-C₂₀ carbocyclic aryl, and Ar₂ and Ar₃ being an optionally substituted C₆-C₂₀ heteroaryl; R₃ is a chlorine atom or a C₁-C₅ straight alkyl; and at least one of R₁ and R₃ is a chlorine atom. In this embodiment, in the Formula (2), R₄, R₅, and R₆ are each independently a hydrogen atom or a C₁-C₅ straight alkyl; R₇ is defined as for R₂; R₈ is —(CH₂)ₘ—NR₁′R₂′, with m being an integer ranging from 1 to 5 and each of R₁′ and R₂′ being independently a C₁-C₅ straight alkyl. In this embodiment, in the Formula (3), R₉, R₁₀, and R₁₁ are each independently a hydrogen atom or a C₁-C₅ straight alkyl; R₁₂ is defined as for R₂; and R₁₃ is a hydrogen atom, a C₁-C₅ straight alkyl, or an optionally substituted C₆-C₂₀ carbocyclic aryl.

In an embodiment, the structural unit presented by the Formula (1) and the structural unit presented by the Formula (2) independently are each present in the resin in an amount of 10 to 90 mol %, preferably 10 to 85 mol %, based on the total number of moles of the structural units represented by the Formulae (1), (2), and (3); and the structure unit presented by the Formula (3) is present in the resin in an amount of 0 to 70 mol %, preferably 5 to 40 mol %, based on the total number of moles of the structural units represented by the Formulae (1), (2), and (3).

In an embodiment, the resin has a weight average molecular weight (Mw) of 1,000 to 10,000,000 Daltons and a molecular weight distribution (Mw/Mn) of 1.5 to 3.

In an embodiment, the resin is present in the coating composition in an amount of 50 to 99 wt %, preferably 90 to 99 wt %, based on the total amount of the dry components of the composition.

In an embodiment, the coating composition further comprises a component having a chromophore group and/or the resin comprises a structural unit derived from a substance having a chromophore group, where the chromophore group is an optionally substituted C₆-C₂₀ aryl, preferably optionally substituted phenyl, naphthyl, or anthracenyl.

In a further embodiment, the substance having a chromophore group is selected from one or more of styrene, phenyl acrylate, benzyl acrylate, benzyl methacrylate, naphthalene alkyl acrylate, naphthalene alkyl methacrylate, anthracene alkyl acrylate, and anthracene alkyl methacrylate.

In a further embodiment, the component having a chromophore group is present in the coating composition in an amount of 0.1 to 3 wt % based on the total amount of the dry components of the coating composition.

In an embodiment, the coating composition further comprises one or more of a surfactant, a leveling agent, and an organic solvent.

In a further embodiment, the coating composition comprises 2 to 10 wt % of the resin, 0.01 to 5 wt % of a surfactant, 0.01 to 5 wt % of a leveling agent, and 85 to 95 wt % of an organic solvent.

Another aspect of the present disclosure provides a method for forming a photoresist relief image on an electronic device, comprising: applying the coating composition according to the present disclosure to the electronic device and heating to form a bottom antireflective coating, forming a photoresist layer on the bottom antireflective coating, and subjecting the photoresist layer to be exposed and developed to form a photoresist relief image.

In an embodiment, a chemically amplified photoresist suitable for imaging at 248 or 193 nm is used to form the photoresist layer on the bottom antireflective coating.

The essential for the present disclosure is that a polymer containing tertiary amino and chloro groups and a structural unit derived from an acrylic polymer in certain proportions is employed as the resin component of the antireflective coating composition. To achieve a smooth crosslinking and curing property, it is sufficient simply to heat the inventive coating composition at high temperature. Furthermore, variation in thickness of bottom antireflective coating films formed by the composition is extremely small. Therefore, the antireflective coating composition according to the present disclosure is very promising.

### DETAILED DESCRIPTION OF THE EMBODIMENTS

The bottom antireflective coating composition according to the present disclosure comprises a resin, which contains a structural unit represented by the Formula (1), a structural unit represented by the Formula (2), and a structural unit represented by the Formula (3), and can be presented by the Formula (4):

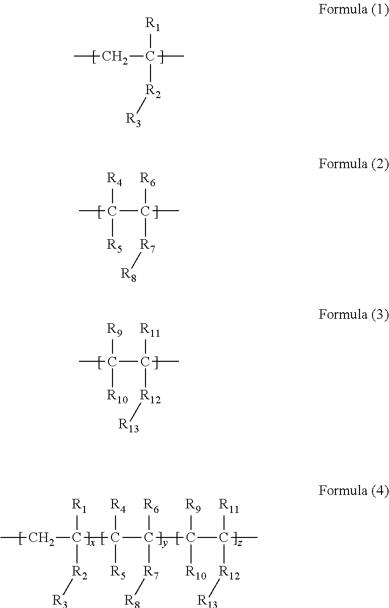

R₁ is a hydrogen atom, a chlorine atom, an optionally substituted alkyl, or an optionally substituted cycloalkyl, preferably a hydrogen atom, a chlorine atom, or a C₁-C₅ straight alkyl. R₄, R₅, R₆, R₉, R₁₀, and R₁₁ are each independently a hydrogen atom, an optionally substituted alkyl, or an optionally substituted cycloalkyl, preferably a hydrogen atom or a C₁-C₅ straight alkyl. R₂, R₇, and R₁₂ are each independently —C(═O)—O—, —O—, —(CH₂)ₙ₁—O—, —O—(CH₂)ₙ₂—, —(CH₂)ₙ₃—, —Ar₁—O—, —O—Ar₂—, or —Ar₃—, with n1 and n2 each being a positive integer and n3 being a non-negative integer and each of Ar₁, Ar₂, and Ar₃ being independently an optionally substituted carbocyclic aryl or an optionally substituted heteroaryl. Preferably, R₂, R₇, and R₁₂ are each independently —C(═O)—O—, —(CH₂)ₙ₁—O—, —O—(CH₂)ₙ₂—, —(CH₂)ₙ₃—, —Ar₁—O—, —O—Ar₂—, or —Ar₃—, with n1 and n2 each being a positive integer ranging from 1 to 6 and n3 being a non-negative integer ranging from 0 to 6, Ar₁ being an optionally substituted C₆-C₂₀ carbocyclic aryl, and Ar₂ and Ar₃ being an optionally substituted C₆-C₂₀ heteroaryl. R₃ is a chlorine atom, an optionally substituted alkyl, or an optionally substituted cycloalkyl, preferably a chlorine atom or C₁-C₅ straight alkyl. At least one of R₁ and R₃ is a chlorine atom. R₈ is an optionally substituted alkyl or an optionally substituted cycloalkyl and contains at least one tertiary amino group. Preferably, R₈ is —(CH₂)ₘ—NR₁′R₂′, with m being an integer ranging from 1 to 5 and each of R₁′ and R₂′ being independently a C₁-C₅ straight alkyl. R₁₃ is a hydrogen atom, an optionally substituted alkyl, an optionally substituted cycloalkyl, or an optionally substituted aryl, preferably a hydrogen atom, C₁-C₅ straight alkyl, or optionally substituted C₆-C₂₀ carbocyclic aryl.

The tertiary amino and chloro groups of the resin comprised in the coating composition according to the present disclosure enable the coating composition to be cured simply by heating (at 180° C. or higher) without addition of a crosslinker component or use of an acid as a catalyst or an acid generating compound and without generating any volatile substance having a low molecular weight, such as less than 500, less than 400, less than 300, less than 200, or even less than 100.

The resin component of the coating composition according to the present disclosure contains at least the three structure units as described above. The resin may be a terpolymer consisting of those three structure units (three different structure units), a tetrapolymer (i.e., four different structure units) consisting of those three structure units, or a higher polymer. These polymers may be produced by copolymerizing corresponding monomers via any polymerization process that is well known to those skilled in the art and thus will not be described in more detail herein. The monomers may be copolymerized in a random, alternating or block-like manner.

If the number of moles of the structural units represented by the Formulae (1), (2), and (3) present in the resin component of the coating composition according to the present disclosure are described as x, y, and z, respectively, x:y:z=(0.1-1000):(0.1-1000):1. Accordingly, the structural unit represented by the Formula (1) and the structural unit represented by the Formula (2) independently are each present in the resin in an amount of 0.1 to 1000 mol, such as 0.1 mol, 0.5 mol, 1 mol, 1.5 mol, 2 mol, 2.5 mol, 3 mol, 3.5 mol, 4 mol, 4.5 mol, 5 mol, 5.5 mol, 6 mol, 6.5 mol, 7 mol, 7.5 mol, 8 mol, 8.5 mol, 9 mol, 9.5 mol, 10 mol, 15 mol, 20 mol, 25 mol, 30 mol, 35 mol, 40 mol, 45 mol, 50 mol, 60 mol, 70 mol, 80 mol, 90 mol, 100 mol, 200 mol, 300 mol, 400 mol, 500 mol, 600 mol, 700 mol, 800 mol, 900 mol, or 1000 mol, based on one mole of the structural unit represented by the Formula (3). In particular, the structural unit represented by the Formula (1) and the structural unit represented by the Formula (2) independently may be each present in the resin in an amount of 10 to 90 mol %, preferably 10 to 85 mol %, such as, 10 mol %, 15 mol %, 20 mol %, 25 mol %, 30 mol %, 35 mol %, 40 mol %, 45 mol %, 50 mol %, 55 mol %, 60 mol %, 65 mol %, 70 mol %, 75 mol %, 80 mol %, or 85 mol % based on the total number of moles of the structural units represented by the Formulae (1), (2), and (3), and the structural unit represented by the Formula (3) may be present in the resin in an amount of 0.1 to 70 mol %, preferably 5 to 40 mol %, such as, 5 mol %, 10 mol %, 15 mol %, 20 mol %, 25 mol %, 30 mol %, 35 mol %, or 40 mol % based on the total number of moles of the structural units represented by the Formulae (1), (2), and (3).

The resin may have a weight average molecular weight (Mw) of 1,000 to 10,000,000 Daltons, preferably 5,000 to 50,000 Daltons, and a molecular weight distribution (Mw/Mn) of 1.5 to 3, preferably 1.8 to 3. The weight average molecular weight and the molecular weight distribution may be measured by gel permeation chromatography (GPC). The resin component may be present in the coating composition in an amount of 50 to 99 wt %, preferably 90 to 99 wt %, based on the total amount of the dry components (all components except solvent) of the coating composition.

In order to provide for an antireflective effect, the coating composition according to the present disclosure preferably further comprises a component having a chromophore group and/or the resin comprises a structural unit derived from a substance having a chromophore group, the chromophore group being useful for absorption of reflections of photoresist exposure radiation. Accordingly, a substance having a chromophore group may be added to, and thus become a further component of the coating composition according to the present disclosure, or may be present in the resin as a structure unit. The chromophore group may be an optionally substituted aryl group having 6 to 20 carbon atoms, preferably an optionally substituted carbocyclic aryl, such as, optionally substituted phenyl, naphthyl, or anthracenyl. Examples of such a substance having a chromophore group include, but are not limited to: styrene, phenyl acrylate, benzyl acrylate, benzyl methacrylate, naphthalene alkyl acrylate, naphthalene alkyl methacrylate, anthracene alkyl acrylate, and anthracene alkyl methacrylate. For example, if the coating composition according to the present disclosure is intended to be used with a photoresist for imaging at sub-200 nm wavelengths such as 193 nm, the chromophore group is preferably a substituted phenyl group. Accordingly, the component or substance having a chromophore group may be styrene, phenyl acrylate, benzyl acrylate, or methacrylic acid. In another example, if the coating composition according to the present disclosure is intended to be used with a photoresist for imaging at sub-300 nm wavelengths such as 248 nm, the chromophore group is preferably a substituted naphthyl or anthracenyl group. Accordingly, the component or substance having a chromophore group may be a compound having a naphthyl group, such as naphthalene alkyl acrylate or naphthalene alkyl methacrylate, or a compound having an anthracenyl group, such as, anthracene alkyl acrylate, or anthracene alkyl methacrylate. Furthermore, the component having a chromophore group may be present in the coating composition in an amount of 0.1 to 3 wt % based on the total amount of the dry components of the composition.

The coating composition according to the present disclosure may further comprise a surfactant and/or other additive(s). The surfactant is commercially available, and for example, FC171, FC431 and so on (trade name) available from Sumitomo 3M in Japan. The surfactant may be present in the composition in an amount of 0.1 to 5 wt % based on the total amount of the dry components of the composition. The additive may be a leveling agent, such as for example Silwet 7604 (trade name) available from Union Carbide, and may be present in the composition in an amount of 0.1 to 5 wt % based on the total amount of the dry components of the composition.

The antireflective coating composition according to the present disclosure is typically used in the form of a solution so that it can be applied to a substrate by spin coating. An organic solvent as a component of the coating composition is preferably selected from one or more of an ester solvent, a glycol ether solvent, and a solvent comprising an ether group and a hydroxyl group. Examples of the ester solvent include, but are not limited to, one or more of oxo isobutyric acid ester, methyl-2-hydroxyisobutyrate, ethyl lactate, methyl cellosolve acetate, ethyl cellosolve acetate, propylene glycol monomethyl ether acetate, dipropylene glycol monomethyl ether acetate, propylene carbonate, and γ-butyrolactone. Examples of the glycol ether solvent include, but are not limited to, one or more of 2-methoxyethyl ether (diethylene glycol dimethyl ether), ethylene glycol monomethyl ether, and propylene glycol monomethyl ether. Examples of the solvent comprising an ether group and a hydroxyl group include, but are not limited to, methoxy butanol, ethoxy butanol, 1-methoxy-2-propanol, and 1-ethoxy-2-propanol. The organic solvent may be used in a quantity such that the bottom antireflective coating composition according to the present disclosure has a solid content of 0.5 to 20 wt %, preferably 0.5 to 10 wt %.

The coating composition according to the present disclosure is typically useful for use with various photoresist compositions. The coating composition is applied on a substrate by spin coating to form a coating layer thereon. The substrate may be suitably any substrate used in processes involving photoresists, such as, a silicon (Si), silicon dioxide (SiO₂), gallium arsenide (GaAs), silicon carbide (SiC), copper, quartz, or ceramic substrate. Preferably, the coating layer of the coating composition according to the present disclosure is crosslinked and thereby cured by heating before a photoresist composition is applied thereon. The curing conditions are selected such that the cured coating layer is substantially insoluble in the photoresist composition solution and in an aqueous alkaline developer solution which is used in a later developing process. The curing may be carried out at 150 to 250° C. for 0.5 to 5 min. The cured coating layer of the coating composition according to the present disclosure typically has a thickness of 0.02 to 0.5 m, preferably 0.02 to 0.2 m. Then, the photoresist composition may be coated on the cured coating layer and then exposed and developed to form a photoresist relief image. The overlying photoresist used with the coating composition according to the present disclosure may be any conventional photoresist, preferably chemically amplified photoresists, suitable for imaging at short wavelengths, such as, 248 nm or 193 nm.

The present disclosure further provides a method for forming a photoresist relief image on an electronic device, comprising: applying the antireflective coating composition according to the present disclosure on the electronic device and heating to form a bottom antireflective coating layer, forming a photoresist layer on the bottom antireflective coating layer, and subjecting the photoresist layer to be exposed and developed to form a photoresist relief image.

In a particular embodiment, after the coating composition according to the present disclosure is applied on the electronic device and cured to form a bottom antireflective coating layer, a photoresist is applied on the coating layer by spin coating and then dried by heating. It is preferred that mixing of the bottom antireflective coating and the photoresist does not occur during this process. The photoresist layer is imagewise exposed through a photomask to a source of activating radiation. Following exposure of the photoresist layer, a post-exposure bake may be performed, if necessary, to thereby increase the differences in solubility between the exposed and unexposed areas of the photoresist layer. Then, the photoresist layer is developed by using a water-based developer fluid, which is typically an aqueous alkaline developer solution. Typically, following development the photoresist layer is baked at 100 to 150° C. for several minutes to harden the exposed and developed areas thereof. Then, the areas of the substrate that are not covered by the photoresist may be processed by using a predetermined processing method including chemical etching or electro plating. For chemical etching, for example, plasma etching may be used, or a hydrofluoric acid solution may be used as an etching solution.

Preferably, a chemically amplified photoresist suitable for imaging at 248 or 193 nm is employed as the photoresist to form the photoresist layer overcoated on the bottom antireflective coating layer formed by the coating composition according to the present disclosure. Such a chemically amplified photoresist is well known to those skilled in the art and therefore will not be described in detail herein.

The present disclosure will now be described in more detail with reference to Examples of the various embodiments but to which the present disclosure is not limited, and to Comparative Examples.

Monomers, initiators, and solvents used in the Examples and Comparative Examples are as follows.

Monomers: styrene (SM), methyl methacrylate (MMA), 2-chloropropene (2-CP), tert-butyl methacrylate (tBMA), dimethylamino ethyl methacrylate (DMA), 2-hydroxyethyl methacrylate (HEMA), 4-acetoxystyrene (ASM), and 2-(9-anthranyl) ethyl acrylate (ANTA).

Initiator: azobisisobutyronitrile (AIBN)

Solvents: tetrahydrofuran (THF), isopropanol (IPA), and methyl 2-hydroxyisobutyrate (HBM).

In the Examples and Comparative Examples, the molecular weight of the resins was measured by gel permeation chromatography (GPC) using THF as eluent and using polystyrene standard.

### Example 1—Preparation of Resin 1 (SM12-CP/DMA, Molar Ratio 20:40:40)

The reactor used was a 3-necked round bottom flask fitted with a magnetic stirrer, a temperature sensor, a dropping funnel, a water-cooled condenser, an injection line for connecting a pump and an injector, and a nitrogen inlet. 21.43 g (280 mmol) of 2-CP and 40 g of HBM were added to the flask. 1.6 g of AIBN and 15 g of HBM were added to the dropping funnel. 14.58 g (140 mmol) of SM, 44.02 g (280 mmol) of DMA, and 132 g of HBM were added to the injector, which was then mounted on the pump. The content of the flask was heated to 60° C., and the content of the dropping funnel was added dropwise. The content of the injector was continuously transferred into the flask in 3 to 3.5 h. After feeding was completed, the reaction was continued at 60° C. for 0.5 h. At the end of this time, heat was removed, and the polymer solution was diluted with solvent and quenched. The resulting polymer solution was then allowed to cool to room temperature and diluted with HBM to a concentration of 20 wt %. Then, the polymer solution was precipitated into IPA. The polymer product was collected via vacuum filtration and dried under vacuum at 60° C. for 24 h to yield a solid, i.e. Resin 1, having a weight average molecular weight of 17,400 and a molecular weight distribution of 2.17.

### Example 2—Preparation of Resin 2 (ANTA/2-CP/DMA, Molar Ratio 10:40:50)

Resin 2 was prepared by the same method as in Example 1, except that 21.43 g (280 mmol) of 2-CP and 80 g of HBM were added to the flask, 1.9 g of AIBN and 15 g of HBM added to the dropping funnel, and 19.34 g (70 mmol) of ANTA, 55.02 g (350 mmol) of DMA, and 128 g of HBM added to the injector.

Resin 2 had a weight average molecular weight of 12,700 and a molecular weight distribution of 1.99.

### Example 3—Preparation of Resin 3 (SM/MMA/2-CP/DMA, Molar Ratio 20:20:30:30)

Resin 3 was prepared by the same method as in Example 1, except that 16.07 g (210 mmol) of 2-CP and 30 g of HBM were added to the flask, 1.3 g of AIBN and 15 g of HBM added to the dropping funnel, and 14.02 g (140 mmol) of MMA, 33.01 g (210 mmol) of DMA, 14.58 g (140 mmol) of SM, and 105 g of HBM added to the injector.

Resin 3 had a weight average molecular weight of 21,400 and a molecular weight distribution of 2.33.

### Example 4—Preparation of Resin 4 (ANTA/MMA/2-CP/DMA, Molar Ratio 10:30:30:30)

Resin 4 was prepared by the same method as in Example 1, except that 16.07 g (210 mmol) of 2-CP and 40 g of HBM were added to the flask, 1.78 g of AIBN and 15 g of HBM added to the dropping funnel, and 21.03 g (210 mmol) of MMA, 33.01 g (210 mmol) of DMA, 19.34 g (70 mmol) of ANTA, and 152 g of HBM added to the injector.

Resin 4 had a weight average molecular weight of 13,400 and a molecular weight distribution of 2.33.

### Example 5—Preparation of Resin 5 (SM/tBMA/2-CP/DMA, Molar Ratio 20:20:30:30)

Resin 5 was prepared by the same method as in Example 1, except that 16.07 g (210 mmol) of 2-CP and 30 g of HBM were added to the flask, 1.67 g of AIBN and 15 g of HBM added to the dropping funnel, and 19.88 g (140 mmol) of tBMA, 33.01 g (210 mmol) of DMA, 14.58 g (140 mmol) of SM, and 150 g of HBM added to the injector.

Resin 5 had a weight average molecular weight of 16,800 and a molecular weight distribution of 2.87.

### Comparative Example 1—Preparation of Resin 6 (SM/MMA/ASM, Molar Ratio 20:20:60)

To a 500 mL four-necked flask, 68.1 g (420 mmol) of ASM, 14.02 g (140 mmol) of MMA, and 14.58 g (140 mmol) of SM were added. Then, 1.93 g of AIBN, as a polymerization initiator, and 225 g of THF, as a solvent, were added and reacted at 65 to 70° C. for 18 h. Thereafter, a dilute aqueous hydrochloric acid solution was added and the reaction continued at 60° C. for 5 h to remove the acetyl protecting group. Then, heat was removed, and the resulting polymer solution was allowed to cool to room temperature and diluted with THF to a concentration of 20 wt %. The polymer solution was precipitated into deionized water. The polymer product was collected via vacuum filtration and dried under vacuum at 60° C. for 24 h to yield a solid, i.e. Resin 6, having a weight average molecular weight of 16,300 and a molecular weight distribution of 2.37.

### Comparative Example 2—Preparation of Resin 7 (SM/MMA/HEMA, Molar Ratio of 20:20:60)

Resin 7 was prepared by the same method as in Example 1, except that 14.58 g (140 mmol) of SM and 50 g of HBM were added to the flask, 1.78 g of AIBN and 15 g of HBM added to the dropping funnel, and 14.02 g (140 mmol) of MMA, 54.7 g (420 mmol) of HEMA, and 130 g of HBM added to the injector.

Resin 7 had a weight average molecular weight of 14,500 and a molecular weight distribution of 2.48.

### Comparative Example 3—Preparation of Resin 8 (MMA/ASM, Molar Ratio 25:75)

Resin 8 was prepared by the same method as in Comparative Example 1, except that 14.02 g (140 mmol) of MMA, 68.1 g (420 mmol) of ASM, 1.17 g of AIBN, and 192 g of THF (as a solvent) were added to the flask. Resin 8 had a weight average molecular weight of 18,400 and a molecular weight distribution of 2.29.

Preparation of Bottom Antireflective Coating Compositions Comprising Resins 1-5 Prepared in Examples 1-5:

The resin was mixed with HBM (as a solvent), FC171 (as a surfactant), and Silwet 7604 (as a leveling agent) by stirring to give a homogeneous mixture. The mixture was filtered through a 0.45 m PTFE filter to obtain the composition. Table 1 lists the constitutions of the compositions.

Preparation of Comparative Coating Compositions Comprising Resins 6-8 Prepared in Comparative Examples 1-3:

Each composition was comprised of 4.5 wt % of the resin, 0.4 wt % of tetramethoxymethyl glycoluril (as a crosslinker), 0.1 wt % of ammonium toluene-4-sulphonate, 0.1 wt % of FC171 (as a surfactant), and 94.9 wt % of HBM (as a solvent). These components were mixed together in proportion by stirring to give a homogeneous mixture. The mixture was filtered through a 0.45 m PTFE filter to obtain the composition.

TABLE 1

| | | | Leveling | |
|---|---|---|---|---|
| | Resin/ | Surfactant/ | agent/ | Solvent/ |
| Example | wt % | wt % | wt % | wt % |
| 1 | Resin 1 (4.5) | 0.1 | 0.1 | 95.3 |
| 2 | Resin 2 (4.5) | 0.1 | 0.1 | 95.3 |
| 3 | Resin 3 (4.5) | 0.1 | 0.1 | 95.3 |
| 4 | Resin 4 (4.5) | 0.1 | 0.1 | 95.3 |
| 5 | Resin 5 (4.5) | 0.1 | 0.1 | 95.3 |

### Test Example 1—Solvent Resistance Test on Samples of the Coating Compositions

Samples of the compositions prepared in the Examples and in the Comparative Examples were applied on respective silicon wafers (4 cm by 4 cm in dimension) by spin coating at 2,000 rpm for 30 s. The wafers were then baked at temperatures shown in Table 2 for 60 s. Thereafter, the coating films were characterized by ellipsometry to determine the thickness L0. A certain volume of HBM was poured onto the surface of the coating films and left standing there for 60 s. Rotary drying was then conducted at a rotating speed of 4,000 rpm for 60 s to remove the solvent. The films were again characterized to determine the current thickness L1. Thickness change rate was calculated in accordance with the following equation: ΔD=(L1−L0)/L0×100%. The results are shown in Table 2.

TABLE 2

Thickness change rate (%)

| | 150° C. | 170° C. | 190° C. | 210° C. |
|---|---|---|---|---|
| Ex. 1 | −10.9% | −2.3% | −0.9% | −0.3% |
| Ex. 2 | — | −3.9% | −1.5% | −0.4% |
| Ex. 3 | −14.8% | −2.5% | −0.8% | −0.7% |
| Ex. 4 | — | −4.6% | −2.8% | −1.9% |
| Ex. 5 | — | −3.1% | −1.1% | −1.2% |
| Comp. Ex. | — | −4.1% | −1.2% | −0.9% |
| 1 | | | | |
| Comp. Ex. | — | −4.5% | −0.9% | −1.0% |
| 2 | | | | |
| Comp. Ex. | — | −3.9% | −0.8% | −0.7% |
| 3 | | | | |

### Test Example 2—Analysis on Film Shrinkage

Samples of the compositions prepared in the Examples and in the Comparative Examples were applied on respective silicon wafers (4 cm by 4 cm in dimension) by spin coating at 2,000 rpm for 30 s such that the coating films formed on the wafers had a thickness within the range of 750 to 800 Å. The accurate thickness L0′ of the films before cure was then measured. The wafers were then baked at temperatures shown in Table 3 for 60 s. The final thickness L1′ of the films after cure was then measured. The shrinkage ratio of the films was calculated in accordance with the following equation: Å=L0′−L1′. The results are shown in Table 3.

TABLE 3

| | Curing Temperature/ | Shrinkage Ratio/ |
|---|---|---|
| | ° C. | Å |
| Ex. 1 | 190 | 63 |
| Ex. 2 | 190 | 70 |
| Ex. 3 | 210 | 90 |
| Ex. 4 | 210 | 83 |
| Ex. 5 | 190 | 66 |
| Comp. Ex. 1 | 210 | 124 |
| Comp. Ex. 2 | 190 | 117 |
| Comp. Ex. 3 | 190 | 130 |

### Example 6—Lithographic Process

This example is provided merely to illustrate that the coating composition according to the present disclosure is useful to form an antireflective coating under a 193 nm photoresist material.

Samples of the compositions prepared in Examples 1, 3, and 5 were applied on respective silicon wafers having a diameter of 150 mm by spin coating at 2,000 rpm and cured by baking at 210° C. for 60 s so as to form a bottom antireflective coating (BARC) thereon. Then, a 193 nm photoresist material was spin-coated onto the BARC layer, baked at 125° C. for 60 s, and exposed to radiation using an ArF scanner with an NA of 0.78 through a mask. Following exposure, a post-exposure bake was performed at 110° C. for 60 s. Then, the photoresist layer was developed in a TMAH developer solution.

While various embodiments of the present disclosure have been described above, it should be understood that they have been presented by way of example only, and not by way of limitation. Many changes, modifications, substitutions, and alterations may be made by those skilled in the art without departing from the spirit and scope of the disclosure.

Claimed is:

1. A bottom antireflective coating composition, comprising a resin containing a structural unit represented by the Formula (1), a structural unit represented by the Formula (2), and a structural unit represented by the Formula (3): 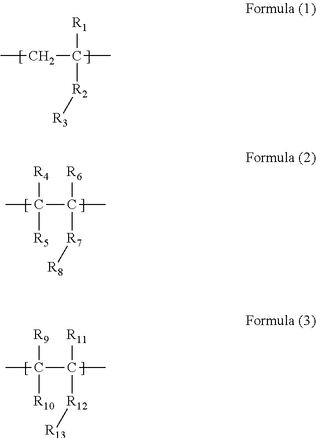
wherein,
in the Formula (1), R₁ is a hydrogen atom, a chlorine atom, an optionally substituted alkyl, or an optionally substituted cycloalkyl; R₂ is —C(═O)—O—, —O—, —(CH₂)ₙ₁—O—, —O—(CH₂)ₙ₂—, —(CH₂)ₙ₃—, —Ar₁—O—, —O—Ar₂—, or —Ar₃—, with n1 and n2 each being a positive integer and n3 being a non-negative integer, and each of Ar₁, Ar₂, and Ar₃ being independently an optionally substituted carbocyclic aryl or an optionally substituted heteroaryl; R₃ is a chlorine atom, an optionally substituted alkyl, or an optionally substituted cycloalkyl; and at least one of R₁ and R₃ is a chlorine atom;
in the Formula (2), R₄, R₅, and R₆ are each independently a hydrogen atom, an optionally substituted alkyl, or an optionally substituted cycloalkyl; R₇ is defined as for R₂; and R₈ is an optionally substituted alkyl or an optionally substituted cycloalkyl and contains at least one tertiary amino group;
wherein, the tertiary amino and chloro groups enable the coating composition to be cured by heating without addition of a crosslinker component or use of an acid as a catalyst or an acid generating compound and without generating any volatile substance;
in the Formula (3), R₉, R₁₀, and R₁₁ are each independently a hydrogen atom, an optionally substituted alkyl, or an optionally substituted cycloalkyl; R₁₂ is defined as for R₂; and R₁₃ is a hydrogen atom, an optionally substituted alkyl, an optionally substituted cycloalkyl, or an optionally substituted aryl;
and wherein, the structural unit presented by the Formula (1) and the structural unit presented by the Formula (2) independently are each present in the resin in an amount of 10 to 90 mol % based on the total number of moles of the structural units represented by the Formulae (1), (2), and (3); and the structure unit presented by the Formula (3) is present in the resin in an amount of 0.1 to 70 mol % based on the total number of moles of the structural units represented by the Formulae (1), (2), and (3).

2. The coating composition according to claim 1, wherein, in the Formula (1), R₁ is a hydrogen atom, a chlorine atom, or a C₁-C₅ straight alkyl; R₂ is —C(═O)—O—, —(CH₂)ₙ₁—O—, —O—(CH₂)ₙ₂—, —(CH₂)ₙ₃—, —Ar₁—O—, —O—Ar₂—, or —Ar₃—, with n1 and n2 each being a positive integer ranging from 1 to 6 and n3 being a non-negative integer ranging from 0 to 6, Ar₁ being an optionally substituted C₆-C₂₀ carbocyclic aryl, and Ar₂ and Arₙ being an optionally substituted C₆-C₂₀ heteroaryl; R₃ is a chlorine atom or a C₁-C₅ straight alkyl; and at least one of R₁ and R₃ is a chlorine atom;
in the Formula (2), R₄, R₅, and R₆ are each independently a hydrogen atom or a C₁-C₅ straight alkyl; R₇ is defined as for R₂; R₈ is —(CH₂)ₘ—NR₁′R₂′, with m being an integer ranging from 1 to 5 and each of R₁′ and R₂′ being independently a C₁-C₅ straight alkyl;
in the Formula (3), R₉, R₁₀, and R₁₁ are each independently a hydrogen atom or a C₁-C₅ straight alkyl; R₁₂ is defined as for R₂; and R₁₃ is a hydrogen atom, a C₁-C₅ straight alkyl, or an optionally substituted C₆-C₂₀ carbocyclic aryl.

3. The coating composition according to claim 1, wherein, the structural unit presented by the Formula (1) and the structural unit presented by the Formula (2) independently are each present in the resin in an amount of 10 to 85 mol % based on the total number of moles of the structural units represented by the Formulae (1), (2), and (3); and the structure unit presented by the Formula (3) is present in the resin in an amount of 5 to 40 mol % based on the total number of moles of the structural units represented by the Formulae (1), (2), and (3).

4. The coating composition according to claim 1, wherein, the resin has a weight average molecular weight (Mw) of 5,000 to 50,000 Daltons and a molecular weight distribution of 1.5 to 3.

5. The coating composition according to claim 1, wherein, the resin is present in the coating composition in an amount of 50 to 99 wt % based on a total amount of dry components of the composition.

6. The coating composition according to claim 5, wherein, the resin is present in the coating composition in an amount of 90 to 99 wt % based on the total amount of dry components of the composition.

7. The coating composition according to claim 1, wherein, the resin comprises a structural unit derived from a substance having a chromophore group, wherein the chromophore group is an optionally substituted C₆-C₂₀ aryl.

8. The coating composition according to claim 7, wherein, the chromophore group is an optionally substituted phenyl, naphthyl, or anthracenyl;

9. The coating composition according to claim 7, wherein the substance having a chromophore group is selected from a group consisting of: styrene, phenyl acrylate, benzyl acrylate, benzyl methacrylate, naphthalene alkyl acrylate, naphthalene alkyl methacrylate, anthracene alkyl acrylate, anthracene alkyl methacrylate, and combinations thereof.

10. The coating composition according to claim 1, further comprising one or more of a surfactant, a leveling agent, and an organic solvent.

11. The coating composition according to claim 2, further comprising one or more of a surfactant, a leveling agent, and an organic solvent.

12. The coating composition according to claim 3, further comprising one or more of a surfactant, a leveling agent, and an organic solvent.

13. The coating composition according to claim 4, further comprising one or more of a surfactant, a leveling agent, and an organic solvent.

14. The coating composition according to claim 5, further comprising one or more of a surfactant, a leveling agent, and an organic solvent.

15. The coating composition according to claim 6, further comprising one or more of a surfactant, a leveling agent, and an organic solvent.

16. The coating composition according to claim 7, further comprising one or more of a surfactant, a leveling agent, and an organic solvent.

17. The coating composition according to claim 9, further comprising one or more of a surfactant, a leveling agent, and an organic solvent.

18. The coating composition according to claim 10, comprising 2 to 10 wt % of the resin, 0.01 to 5 wt % of the surfactant, 0.01 to 5 wt % of the leveling agent, and 85 to 95 wt % of the organic solvent.

19. A method for forming a photoresist relief image on an electronic device, comprising:
applying the coating composition claim 1 on the electronic device and heating to form a bottom antireflective coating,
forming a photoresist layer on the bottom antireflective coating, and
subjecting the photoresist layer to be exposed and developed to form a photoresist relief image.

20. The method according to claim 19, wherein, a chemically amplified photoresist configured for imaging at 248 or 193 nm is used to form the photoresist layer on the bottom antireflective coating.
